(19) United States
(12) Patent Application Publication
(10) Pub. No.: US 2012/0268900 A1
(43) Pub. Date: Oct. 25, 2012

(54) LATCH MECHANISM FOR A BATTERY UNIT AND ELECTRONIC DEVICE HAVING THE SAME

(75) Inventors: MIN FAN, GUANGZHOU (CN); XI XIANG HU, GUANGZHOU (CN)

(73) Assignees: LITE-ON TECHNOLOGY CORPORATION, TAIPEI CITY (TW); SILITEK ELECTRONIC (GUANGZHOU) CO., LTD., GUANGZHOU (CN)

(21) Appl. No.: 13/175,939

(22) Filed: Jul. 4, 2011

(30) Foreign Application Priority Data
Apr. 21, 2011 (CN) 201120118455.5

(51) Int. Cl. H05K 7/00; E05C 1/10; E05C 1/08

(52) U.S. Cl. 361/747; 292/137; 292/145

(57) ABSTRACT

A latch mechanism for a battery unit includes a locking mechanism having a main body, at least one engaging mechanism, and at least one abutting portion. At least one tenon extends from the main body, and at least one ramp structure having an inclined surface extends from the main body. The engaging mechanism is arranged on a battery unit to receive the tenon. The abutting portion is arranged on the battery unit and has a contacting surface projected toward the inclined surface. When the locking mechanism is moved from the locking position to the released position, the contacting surface is abutted and lifted by the inclined surface, after the tenon has been completely disengaged from the engaging mechanism. The displacement of the contacting surface enables the battery unit to displace away from the inclined surface. The instant disclosure also includes an electronic device having the latch mechanism for a battery unit.

### BACKGROUND OF THE INVENTION

1. Field of the Invention

The instant disclosure relates to a latch mechanism for a battery unit and an electronic device having the same; more particularly, to a latch mechanism for a battery unit having the abilities to release and eject a battery unit for replacement, and can be incorporated to any portable electronic device.

2. Description of Related Art

When changing batteries in a conventional electronic device, a person would often have to use his or her fingers to pop out the batteries from the case. Some battery removal assisting devices are created to address this inconvenient issue. One conventional example of such device is to arrange a ribbon, usually made of a plastic such as Mylar and connected to the battery bay on one end, underneath the batteries. An opposite end of the ribbon is arranged to be freely exposed from the battery bay. The user may release the battery by simply pulling the ribbon to pop it off for replacement.

However, several disadvantages exist for the above techniques. For example, when the batteries are tightly packed, a person would experience a hard time trying to remove the batteries by using his or her fingers. Heavier batteries would have the same issue. Meanwhile, the ribbon could be mishandled by the user to cause inconvenience in changing the batteries.

To address the above issues, the inventor strives via industrial experience and academic research to present the instant disclosure, which can effectively improve the limitations described above.

### SUMMARY OF THE INVENTION

The instant disclosure provides a latch mechanism for a battery unit and an electronic device having the same. Based on a locking mechanism, a battery unit can be released and ejected for replacement.

The latch mechanism comprises a locking mechanism, at least one engaging mechanism, and at least one abutting portion. The locking mechanism can be movably disposed between a locking position and a released position. Structurally, the locking mechanism includes a main body, at least one tenon extended from the main body, and at least one ramp structure extended from the main body in the same direction as the tenon. An upward-facing inclined surface is formed on the ramp structure. The inclined surface slopes downward from the locking position toward the released position. A leading end, where the upward inclination of the inclined surface begins, is defined on the inclined surface. Oppositely, a tail end, where the upward inclination terminates, is defined on the inclined surface. In comparing to the leading end, the tail end is further away from the main body. The engaging mechanism is fixedly arranged on the outer surface of the battery unit and forms a mortise structure to accommodate the tenon. The abutting portion is also fixedly arranged on the outer surface of the battery unit, and forms a contacting surface facing the inclined surface. A leading portion and a tail portion are defined on the contacting surface. The leading portion is further away from the battery unit versus the tail portion. The contacting surface is generally parallel to the inclined surface. When the locking mechanism shifts horizontally from the locking position to the released position, the inclined surface abuts and lifts the contacting surface, after the tenon has exited the mortise structure. Specifically, the leading portion of the contacting surface is moved along the leading end of the inclined surface toward the tail end, while the contacting surface is being displaced normally to the inclined surface. Thereby, the abutting portion is lifted to eject the battery unit by the locking mechanism.

The electronic device comprises a locking mechanism and a battery unit. The locking mechanism can be movably disposed between a locking position and a released position. Structurally, the locking mechanism includes a main body, at least one tenon extended from the main body, and at least one ramp structure extended from the main body in the same direction as the tenon. An upward-facing inclined surface is formed on the ramp structure. The inclined surface slopes downward from the locking position toward the released position. A leading end, where the upward inclination of the sloped surface begins, is defined on the inclined surface. Oppositely, a tail end, where the upward inclination terminates, is defined on the inclined surface. In comparing to the leading end, the tail end is further away from the main body. The battery unit has at least one engaging mechanism and at least one abutting portion. The engaging mechanism is arranged on the periphery of the battery unit and forms a mortise structure to accommodate the tenon. The abutting portion is also arranged on the periphery of the battery unit, and forms a contacting surface facing the inclined surface. A leading portion and a tail portion are defined on the contacting surface. The leading portion is further away from the battery unit in versus the tail portion. The contacting surface is generally parallel to the inclined surface. When the locking mechanism shifts horizontally from the locking position to the released position, the inclined surface abuts and lifts the contacting surface, after the tenon has exited the mortise structure. Specifically, the leading portion of the contacting surface is moved along the leading end of the inclined surface toward the tail end, while the contacting surface is being displaced normally to the inclined surface. Thereby, the abutting portion is lifted to eject the battery unit by the locking mechanism.

Based on the above summary and following detailed descriptions, the instant disclosure and associated claims are explained accordingly.

### DETAILED DESCRIPTION OF PREFERRED EMBODIMENTS

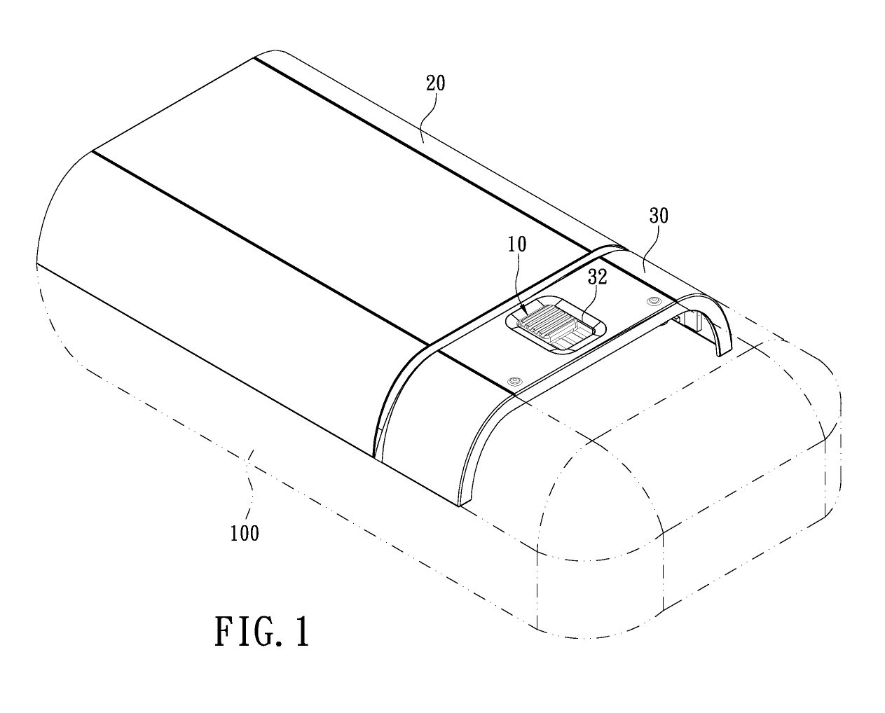

FIG. 1 is a schematic view showing a latch mechanism for a battery unit disposed on an electronic device of the instant disclosure.

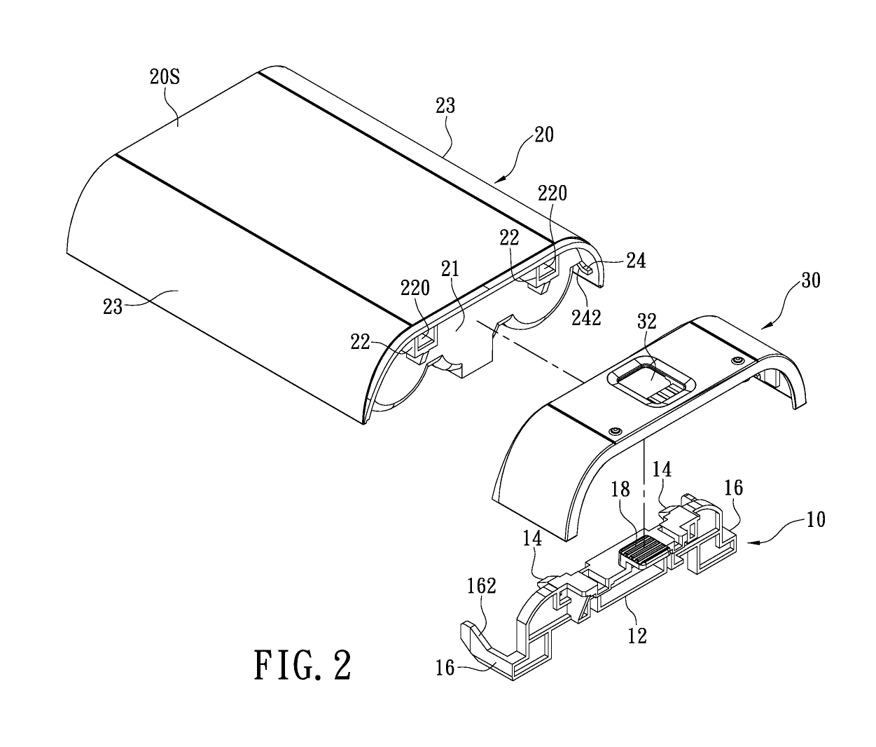

FIG. 2 is an exploded view of the latch mechanism of the instant disclosure.

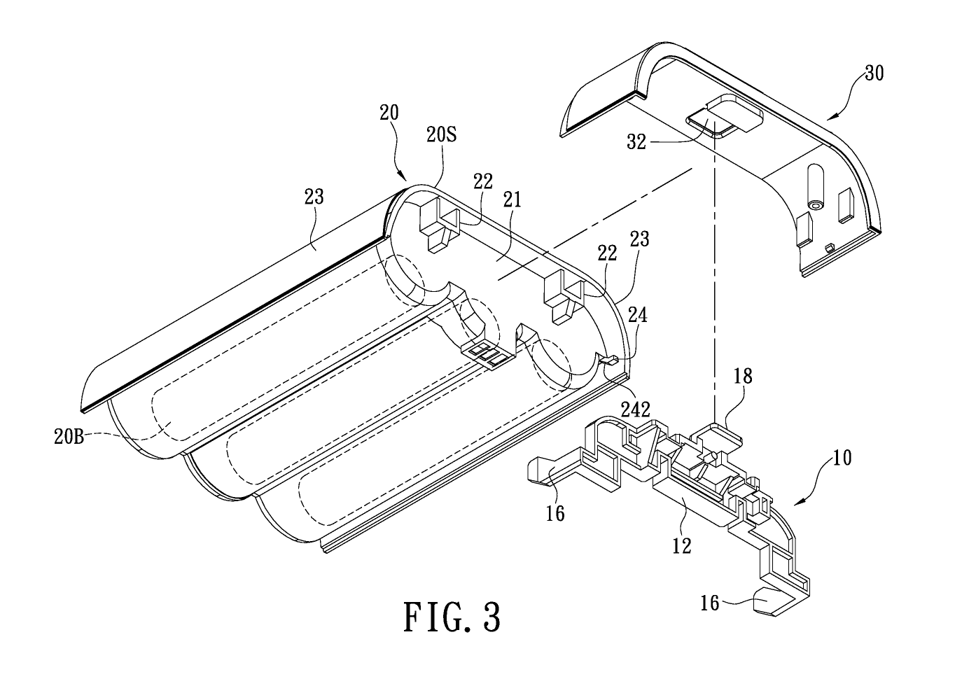

FIG. 3 is another exploded view of the latch mechanism of the instant disclosure.

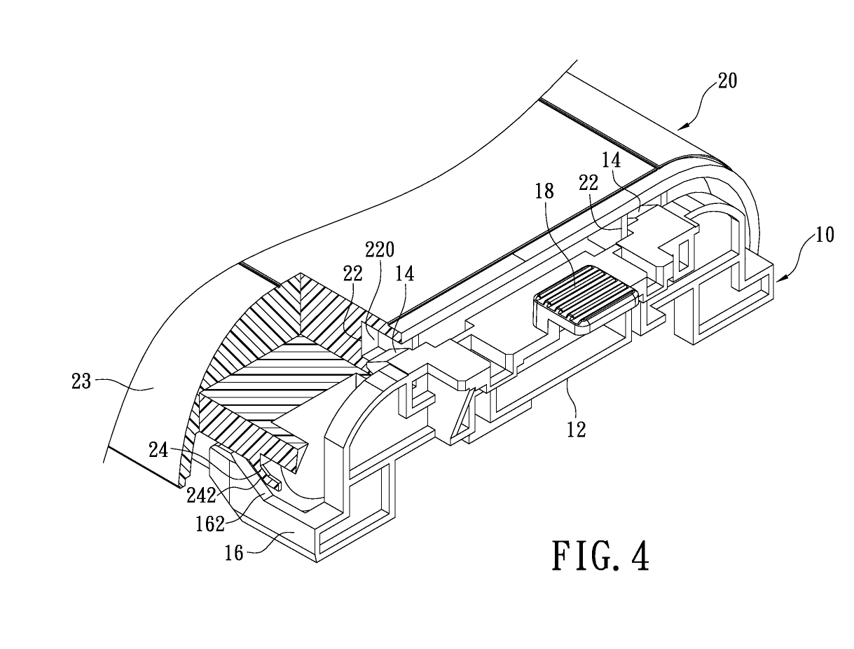

FIG. 4 is a sectional view showing a battery unit in a secured state of the instant disclosure.

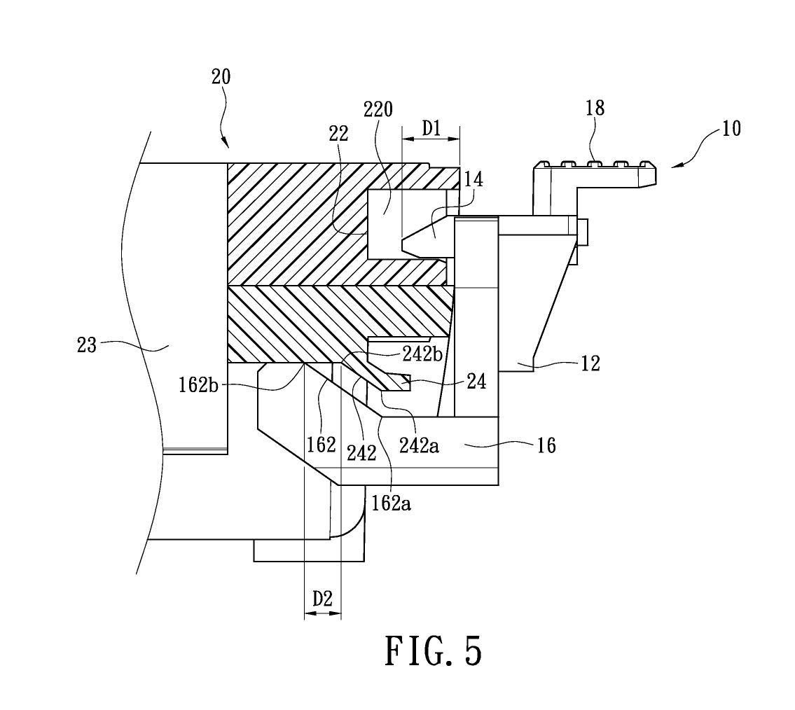

FIG. 5 is another sectional view showing the battery unit in a secured state of the instant disclosure.

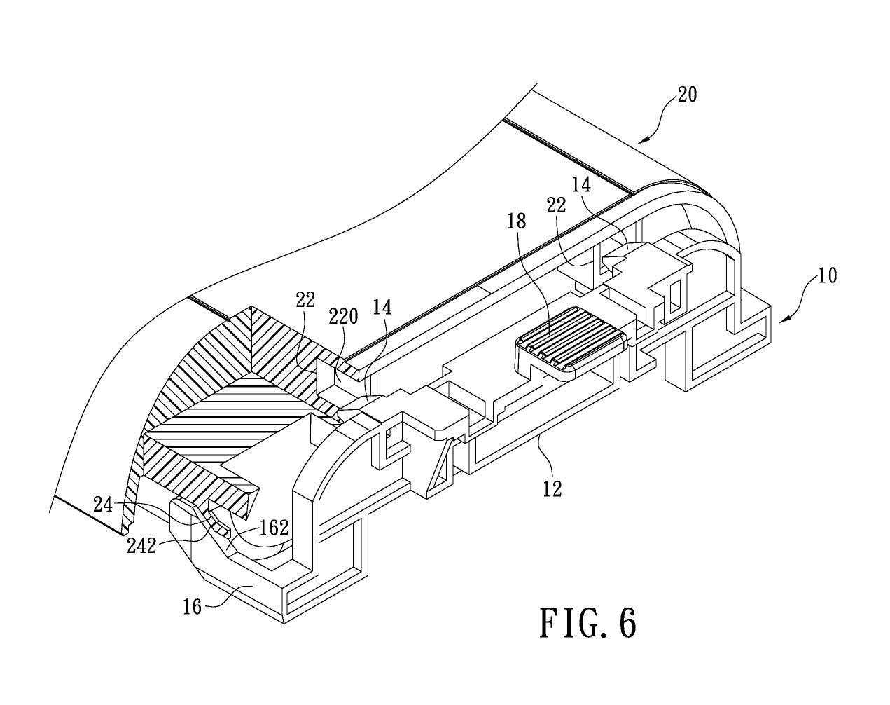

FIG. 6 is a sectional view showing the battery unit in a released state of the instant disclosure.

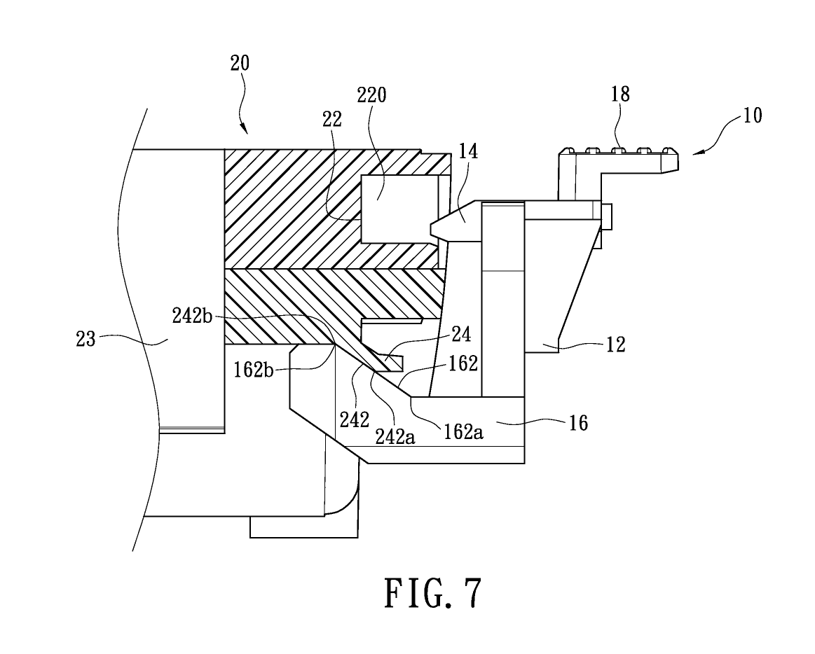

FIG. 7 is another sectional view showing the battery unit in a released state of the instant disclosure.

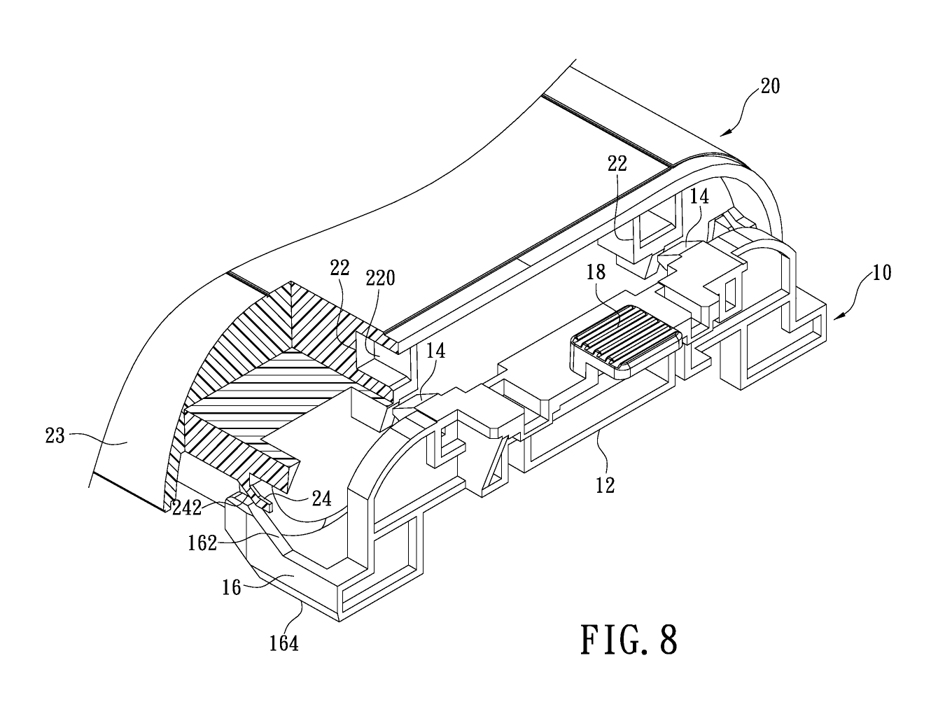

FIG. 8 is a sectional view showing the battery unit in an ejected state of the instant disclosure.

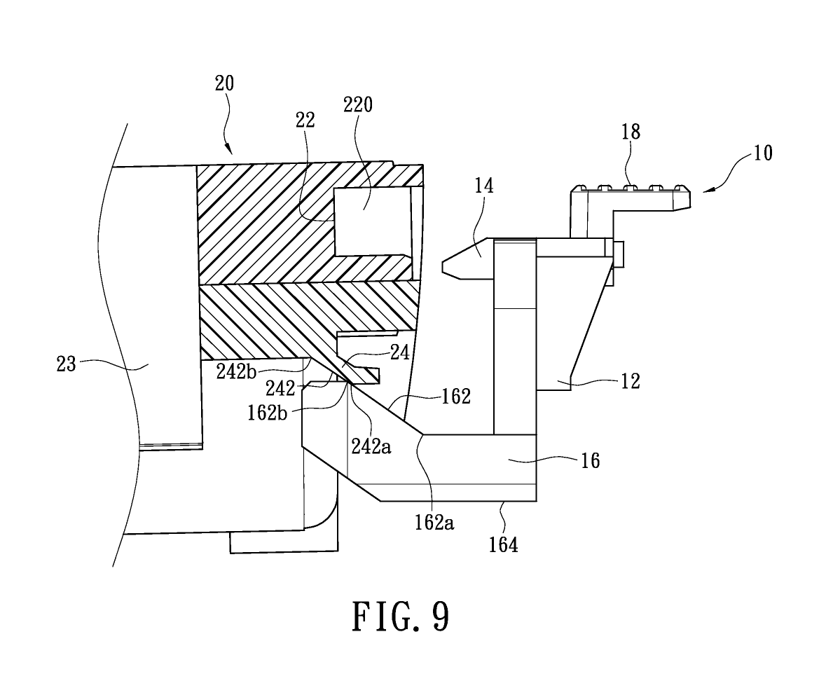

FIG. 9 is another sectional view showing the battery unit in an ejected state of the instant disclosure.

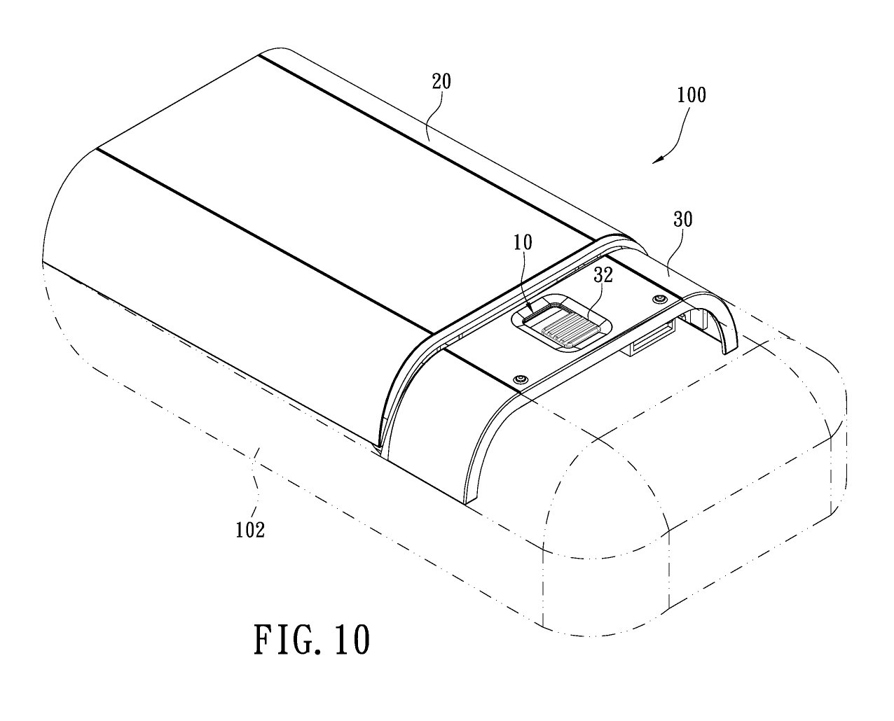

FIG. 10 is a perspective view showing the battery unit in an ejected state on the electronic device of the instant disclosure.

### DETAILED DESCRIPTION OF PREFERRED EMBODIMENTS

To further understand the purpose, structural integrity, features, and functions of the instant disclosure, please refer to the descriptions provided herein.

Please refer to FIG. 1, which shows a latch mechanism for a battery unit disposed on an electronic device of the instant disclosure. The latch mechanism is disposed internally of the electronic device 100. The electronic device 100 includes a battery unit 20. The latch mechanism is especially suitable for portable electronic devices, such as mobile phones, small image projectors, etc. Issues with removing heavier batteries can be particularly addressed by the use of the latch mechanism. For the instant embodiment, as shown in FIGS. 2 and 3, the battery unit 20 has a shell body 20S and a plurality of identical batteries 20B disposed therein. In particular, the shell body 20S is formed integrally with the batteries 20B. However, the structural configuration of the battery unit 20 is not restricted. For example, the shell body 20S can be separately installed over the batteries 20B. For explaining purposes, the battery unit 20 is oriented as shown in the figures. The top surface of the battery unit 20 is defined as facing the upward direction.

Please refer back to FIGS. 2 and 3. The latch mechanism comprises a locking mechanism 10 near the battery unit 20, at least one engaging mechanism 22, and at least one abutting portion 24. The locking mechanism 10 can be selectively moved between a locking position and a released position, thereby securing or freeing the battery unit 20, respectively. When necessary, an elastic member can be used to return the locking mechanism 10 from the released position to the locking position. The locking mechanism 10 is disposed and structurally supported internally of the electronic device 100. As already mentioned, the locking mechanism 10 can be shifted between the locking and released position. The shifting direction is generally along the longitudinal axis of the battery unit 20.

The locking mechanism 10 has a main body 12, at least one tenon 14 extending from the main body 12, and at least one ramp structure 16 extending from the main body 12. For the instant embodiment, the locking mechanism 10 has a pair of tenons 14 extended off the main body 12, and has a pair of ramp structures 16 extended from opposite ends of the main body 12. The locking mechanism 10 further has a pusher 18 connected to the main body 12. The user can move the locking mechanism 10 manually by operating the pusher 18. The tenons 14 are used to lock the battery unit 20 in place, while the ramp structures 16 abut the underside of the battery unit 20. An inclined surface 162 is formed on the ramp structure 16 facing the battery unit 20. As shown in the figures, the inclined surface 162 is facing upward. In other words, the inclined surface 162 is oriented outwardly from the electronic device 100. The inclined surface 162 slopes downwardly toward the released position of the locking mechanism 10. The inclined surface 162 of the ramp structure 16 allows the battery unit 20 to be disengaged and ejected from the electronic device 100.

For the instant embodiment, a protecting cover 30 can be disposed over the locking mechanism 10 and adjacent to the shell body 20S. An opening 32 is formed centrally on the cover 30. The pusher 18 of the locking mechanism 10 can be movably received in the opening 32. For the instant embodiment, when the pusher 18 is at the left portion of the opening 32 (as shown in FIG. 1), the locking mechanism 10 is at the locking position When the pusher 18 is pushed to the right portion of the opening 32 (as shown in FIG. 10), the locking mechanism 10 is moved to the released position.

Additional descriptions are given herein regarding the engaging mechanism 22 and the abutting portion 24 of the latch mechanism. The engaging mechanism 22 is fixedly arranged on the outer surface of the battery unit 20. A mortise structure 220 is projected toward the locking mechanism 10 by the engaging mechanism 22. As illustrated in FIG. 2, the mortise structure 220 is reserved for receiving the tenon 14. Likewise, the abutting portion 24 is also fixedly arranged on the outer surface of the battery unit 20. A contacting surface 242 is formed on the abutting portion 24 parallelly to the inclined surface 162.

For the instant embodiment, the engaging mechanism 22 and the abutting portion 24 are formed integrally with the shell 20S of the battery unit 20. More specifically, the shell 20S has a pair of side surfaces 23 formed thereon. A front surface 21 is also formed on the shell 20S facing toward the locking mechanism 10. The abutting portions 24 are formed on the inner side of the front surface 21. Each engaging mechanism 22 has a frame-like shape formed on the front surface 21 and extends outwardly. The battery unit 20 of the instant disclosure is formed in one piece. However, the battery unit 20 is not restricted structurally. For example, the engaging mechanisms 22 and the abutting portions 24 can be individually disposed on the battery unit 20.

Please refer to FIGS. 4 and 5, which show sectional views of the battery unit 20 and the locking mechanism 10 at the locking position. Please also compare to FIGS. 6 and 7, which show sectional views of the battery unit 20 and the locking mechanism 10 at the released position. When the locking mechanism 10 is moving from the locking position to the released position, or in a left to right direction as shown in FIG. 4, the ramp structure 16 moves toward the corresponding abutting portion 24

As shown in FIGS. 4 and 5, when the battery unit 20 is in a locked state, the tenons 14 are engaged to the mortise structures 220 of the engaging mechanisms 22. The battery unit 20 is fastened securely to the electronic device 100. The ramp structures 16 are separated from the corresponding abutting portions 24 by a specific distance.

With respect to the locking mechanism 10, the horizontal distance between the ramp structure 16 and the abutting portion 24 can be explained as follows. When the locking mechanism 10 is at the locking position, the horizontal distance between the ramp structure 16 and the abutting portion 24 is greater than or equal to the length of the tenon 14 inside the engaging mechanism 22. The reason for such configuration is as follows. When the locking mechanism 10 is at locked position, because the tenon 14 is still engaged to the mortise structure 220, thus the battery unit 20 is locked in place. Only when the tenon 14 of the locking mechanism 10 has moved completely away from the engaging mechanism 22, meaning the battery unit 20 has been completely disengaged by the locking mechanism 10, the ramp structure 16 is able to abut and push the abutting portion 24. In other words, only after the locking mechanism 10 has shifted away from the locking position, with the tenons 14 completely disengaged from the engaging mechanisms 22, the inclined surface 162 of the ramp structure 16 is able to abut the contacting surface 242 of the abutting portion 24.

Please refer to FIGS. 6 and 7. As the locking mechanism 10 is moved from the locking position to the released position, the tenons 14 disengage from the engaging mechanisms 22, thus releasing the battery unit 20 from the locking mechanism 10. In FIGS. 6 and 7, the disengagement of the locking mechanism 10 is implemented horizontally in a left-to-right direction. At such moment, the ramp structures 16 are put against the abutting portions 24. In particular, the inclined surfaces 162 abut the contacting surfaces 242. For the instant embodiment, a leading end 162a is defined on each inclined surface 162 in proximity of the main body 12. A tail end 162b is oppositely defined on each inclined surface 162 further away from the main body 12. Similarly, a leading portion 242a is defined on each contacting surface 242 away from the battery unit 20. A tail portion 242b is defined oppositely on each contacting surface 242 and being closer to the battery unit 20. When the inclined surfaces 162 abut the contacting surfaces 242, the leading portions 242a of the contacting surfaces 242 are contacted by the respective leading ends 162a of the inclined surfaces 162.

Please refer to FIGS. 8 to 10. As the locking mechanism 10 continues to be shifted away from the battery unit 20, namely in a left-to-right direction horizontally, the locking mechanism 10 becomes completely away from the locking position, with the tenons 14 being completely disengaged from the engaging mechanism 22. At such moment, the leading portion 242a of each contacting surface 242 is travelled along the corresponding inclined surface 162 toward the tail end 162b, while the contacting surfaces 242 are being pushed upward by the inclined surfaces 162. More specifically, each ramp structure 16 has a bottom surface 164 (as shown in FIG. 8) supported by a lower shell 102 (FIG. 10) of the electronic device 100. When the locking mechanism 10 is disengaging from the battery unit 20, an upward pushing force is applied from the inclined surfaces 162 on the contacting surfaces 242 based on what the opposite side of the inclined surfaces 162 is the bottom surface 164 supported by the lower shell 102 of the electronic device 100, and causing the abutting portions 24 to displace upward. The battery unit 20 is tilted upward along with the abutting portions 24 away from the inclined surfaces 162 (please compare FIG. 10 with FIG. 1). Thus, the battery unit 20 can be extracted more easily by the user. A perspective view illustrating the battery unit 20 being ejected from the electronic device 100 is shown in FIG. 10. In particular, the edge portion of the battery unit 20 adjacent to the cover 30 is elevated by a certain distance, thus the battery unit 20 can be extracted by the user with greater ease.

The instant disclosure has a simple structure and is cost effective. In addition, the battery unit is ejected from the electronic device immediately after being disengaged by the locking mechanism. The battery removal operation is simply and efficiently performed by the instant disclosure. Unlike conventional techniques, no extra steps are required to extract the battery unit, such as the ribbon-pulling method. For the instant disclosure, the battery unit is ejected automatically when the battery unit is being disengaged.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A latch mechanism for locking and releasing a battery unit, comprising:
a locking mechanism having a main body movably selectable between a locking position and a released position, the locking mechanism having at least one tenon and at least one ramp structure extended from the main body toward substantially the same direction,
wherein the ramp structure defines an inclined surface slopping downward in the direction from the locking position toward the released position;
an engaging mechanism, fixedly arranged on the battery unit, having at least one mortise formed toward the locking mechanism for engaging the tenon in the locking position; and
at least one abutting portion fixedly arranged on the battery unit having a contacting surface corresponding to the ramp structure for establishing sliding contact there-with, the contacting surface being substantially parallel to the inclined surface of the ramp structure;
wherein when the locking mechanism is moved away from the locking position to the released position, the tenon disengages the engaging mechanism and the ramp structure raises the abutting portion in a manner that assists the extraction of the battery unit.

2. The latch mechanism of claim 1, wherein the ramp structure is separated from the abutting portion by moving a distance which is greater than or equal to the length of the tenon inside the engaging mechanism when the locking mechanism is at the locking position.

3. The latch mechanism of claim 1, wherein a leading end is defined on each inclined surface in proximity of the main body, a tail end is oppositely defined on each inclined surface further away from the main body, a leading portion is defined on each contacting surface away from the battery unit, a tail portion is defined oppositely on each contacting surface and being closer to the battery unit, the leading portion of the contacting surface is moved from the leading end of the inclined surface toward the tail end of the inclined surface along the inclined surface when the locking mechanism is moved away from the locking position to the released position.

4. The latch mechanism of claim 1, wherein the locking mechanism further has a pusher connected to the main body.

5. The latch mechanism of claim 4, further comprising a cover adjacent to the battery unit, wherein an opening is formed on the cover to movably receive the pusher.

6. The latch mechanism of claim 1, wherein the engaging mechanism and the abutting portion are integrally arranged on a shell body of the battery unit.

7. The latch mechanism of claim 6, wherein the shell body has a pair of side surfaces and a front surface facing toward the locking mechanism, wherein one abutting portion is formed on the inner side of each side surface, and wherein a pair of engaging mechanisms are formed on the front surface.

8. The latch mechanism of claim 1, wherein the locking mechanism has a pair of tenons extended from the main body and a pair of ramp structures extended from opposite ends of the main body.

9. An electronic device, comprising:
a locking mechanism movably selectable between a locking position and a released position, the locking mechanism having
a main body,
at least one tenon and at least one ramp structure extended from the main body toward substantially the same direction,
wherein the ramp structure defines an inclined surface slopping downward in the direction from the locking position toward the released position;
a battery unit, comprising
an engaging mechanism fixedly arranged on the battery unit having at least one mortise formed toward the locking mechanism for engaging the tenon in the locking position, and
at least one abutting portion fixedly arranged on the battery unit having a contacting surface corresponding to the ramp structure for establishing sliding contact there-with, the contacting surface being substantially parallel to the inclined surface of the ramp structure;
wherein when the locking mechanism is moved away from the locking position, the tenon disengages the engaging mechanism and the ramp structure raises the abutting portion in a manner that assists the extraction of the battery unit.

10. The electronic device of claim 9, wherein the ramp structure is separated from the abutting portion by a distance greater than or equal to the length of the tenon inside the engaging mechanism when the locking mechanism is at the locking position.
